(19) United States
(12) Patent Application Publication
(10) Pub. No.: US 2010/0019300 A1
(43) Pub. Date: Jan. 28, 2010

(54) MULTILAYER INTEGRATED CIRCUIT HAVING AN INDUCTOR IN STACKED ARRANGEMENT WITH A DISTRIBUTED CAPACITOR

(75) Inventors: Shih-An YU, Taipei (TW); Peter R. KINGET, Summit, NJ (US)

Correspondence Address: WilmerHale/Columbia University, 399 PARK AVENUE, NEW YORK, NY, 10022, US

(73) Assignee: THE TRUSTEES OF COLUMBIA UNIVERSITY IN THE CITY OF NEW YORK, New York, NY (US)

(21) Appl. No.: 12/491,608

(22) Filed: Jun. 25, 2009

Related U.S. Application Data
(60) Provisional application No. 61/075,403, filed on Jun. 25, 2008.

(51) Int. Cl. H01L 29/94

(52) U.S. Cl. 257/296; 257/E29.345

(57) ABSTRACT

Some embodiments provide a multilayer integrated circuit, including: a semiconductor substrate including a plurality of channels extending into the substrate from a surface of the substrate; a distributed capacitor including a plurality of gates formed on the surface of the substrate over the channels, and further including an insulator between the gates and the channels, the gates being spaced apart along the surface of the substrate; an interconnect layer formed over the distributed capacitor, the interconnect layer including a plurality of conductors, at least a first conductor being connected to at least some of the gates and at least a second conductor being connected to at least some of the channels; and an inductor formed over the interconnect layer, the inductor including at least conductor arranged on a layer.

### CROSS-REFERENCE TO RELATED APPLICATION

This application claims the benefit under 35 U.S.C. § 119(e) of United States Provisional Patent Application No. 61/075,403, filed Jun. 25, 2008, which is hereby incorporated by reference herein in its entirety.

### TECHNICAL FIELD

The disclosed subject matter relates to a multilayer integrated circuit having an inductor in stacked arrangement with a distributed capacitor.

### BACKGROUND

Circuit designers typically desire to reduce the surface area occupied by integrated circuits, because smaller and/or higher density circuits can be less expensive to produce and can allow for the creation of smaller end products and/or end products having increased capabilities. This is particularly true for integrated circuits that include both analog and digital circuitry, because in many applications, the analog circuits require a significant proportion of the area of the integrated circuit. One way circuit area can be reduced is by trying to arrange the analog circuitry more compactly, such as by arranging analog components closer together or in layers. However, this can lead to other problems, such as interference between components and/or degradation in the performance of the analog circuitry.

A phase locked loop (PLL) is an example of an analog circuit that can occupy significant surface area. PLLs are used, for example, for clock generation in digital integrated circuits, clock recovery in input/output (I/O) circuits, and carrier frequency synthesis in wireless transceivers. One reason that PLLs often occupy significant area is that they incorporate a voltage controlled oscillator, which it turn uses inductor-capacitor-based (LC) resonant circuits. The size of inductors and capacitors is determined in large measure by the operating frequency of the resonant circuit, which makes it difficult as a practical matter to reduce their surface area. Arranging an inductor in a layered structure can result in the formation of eddy currents in adjacent layers. This tends to reduce the quality factor (Q) of the inductor, which can lead to increased noise in the circuit and other undesirable effects.

### SUMMARY

Some embodiments provide a multilayer integrated circuit having an inductor in stacked arrangement with a distributed capacitor. Some embodiments provide a multilayer integrated circuit, including: a semiconductor substrate including a plurality of channels extending into the substrate from a surface of the substrate; a distributed capacitor including a plurality of gates formed on the surface of the substrate over the channels, and further including an insulator between the gates and the channels, the gates being spaced apart along the surface of the substrate; an interconnect layer formed over the distributed capacitor, the interconnect layer including a plurality of conductors, at least a first conductor being connected to at least some of the gates and at least a second conductor being connected to at least some of the channels; and an inductor formed over the interconnect layer, the inductor including at least conductor arranged on a layer.

### BRIEF DESCRIPTION OF THE DRAWINGS

FIG. 1 is a profile view of a simplified illustration of a distributed capacitor, formed of L-shaped sections, arranged under an inductor in accordance with some embodiments of the disclosed subject matter.

FIG. 2 is a top view of a simplified illustration of a distributed capacitor, formed of L-shaped sections, positioned under an inductor in accordance with some embodiments of the disclosed subject matter.

FIG. 3 is a layout plot of a distributed capacitor, formed of L-shaped sections, positioned under an inductor in accordance with some embodiments of the disclosed subject matter.

FIG. 4 is a layout plot, including the layout plot of FIG. 3, of a phase locked loop in accordance with some embodiments of the disclosed subject matter.

FIG. 5 is a photograph of a phase locked loop in 45 nm CMOS technology in accordance with some embodiments of the disclosed subject matter.

FIGS. 6-9 are layout views illustrating the interconnections between L-shaped groups of transistor devices forming a capacitor in accordance with some embodiments of the disclosed subject matter.

FIG. 10 is a diagram of a phase locked loop including a voltage controlled oscillator in accordance with some embodiments of the disclosed subject matter.

FIG. 11 is a diagram of the voltage controlled oscillator of FIG. 10 in accordance with some embodiments of the disclosed subject matter.

FIG. 12 is a diagram of electrical equivalent model of the simplified illustration of FIG. 1 in accordance with some embodiments of the disclosed subject matter.

FIG. 13 is chart illustrating electromagnetic simulation of an inductor with a capacitor arranged underneath in accordance with some embodiments of the disclosed subject matter.

### DETAILED DESCRIPTION

Some embodiments of the disclosed subject matter provide a multilayer integrated circuit (IC) having an inductor in a stacked arrangement with a distributed capacitor. The inductor and capacitor can be connected together to form a resonant circuit, or alternatively, the inductor and capacitor may not be connected together and may serve separate roles in the IC. For example, the inductor could be an inductive load for a stage in the IC (e.g., an amplifier, mixer, etc.), and the capacitor could be part of a loop filter elsewhere in the IC. Even if the inductor is part of a resonator, as in the example PLL implementation discussed below, the capacitor component of the LC resonator need not be the capacitor physically located under the inductor. In the example below, the inductor is part of the LC resonator for a voltage controlled oscillator (VCO), but the capacitor component of the LC resonator is located in another portion of the chip. The distributed capacitor formed beneath the inductor is part of the loop filter circuit for the PLL.

In some embodiments, the multilayer circuit includes a distributed capacitor formed under an inductor that, for example, can serve as shielding from a low resistive substrate to improve the quality factor of the inductor. The capacitor can be a distributed capacitor formed of many smaller capacitor elements arranged and interconnected to avoid and/or reduce current loops that can reduce the quality factor of the inductor. The inductor and capacitor can be used in combination, or separately, in various circuits, such as, for example, integrated PLLs (Phase Locked Loops), oscillators, low-noise or buffer amplifies, mixers, etc.

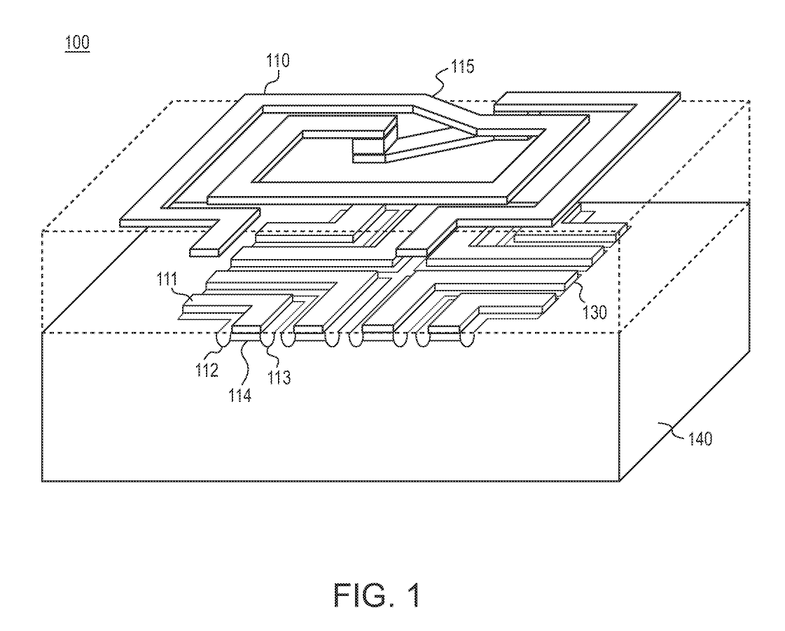

FIG. 1 shows a simplified illustration of a multilayer integrated circuit 100 (“the device”), including substrate 140, metal layers 135, distributed capacitor 130, and inductor 110. The distributed capacitor 130 can be formed of a plurality of gates formed on the surface of substrate 140 over channels (e.g., channel 114), with an insulator between the gates and the channels. For example, a top plate of capacitor 130 can be formed by poly gates of NMOS transistors, and a bottom plate of capacitor 130 can be an inversion layer between drain and source terminals of the transistors, which can be shorted to ground. The source and drains of neighboring transistors can be laid out separately and connected at the center of capacitor 130 so that eddy currents do not flow in the bottom plate (the connections are not shown in FIG. 1).

The distributed capacitor 130 can be formed by interconnecting various smaller capacitor elements. For example, the capacitor 130 can be formed of four groups of a number of nested L-shaped NMOS transistors. Each of the four groups can occupy one quadrant of the device 100, with the largest transistor closest to, and pointed at, the center of device 100. The remaining transistors can be nested, one within the next, in decreasing size order (with the smallest L-shaped transistor closest to the corner of the quadrant that is diagonally opposite from the corner of the quadrant at the center of device 100). Each NMOS transistor can include, among other things, a gate 111, drain 112, source 113, and channel 114 of semi-conductor material (channel 114 can include drain 112 and source 113).

Device 100 can include an interconnect layer formed in the generally lower layers over the substrate 140. For example, the interconnect layer can be located on the second and third lowest metal layers and can include a first conductor connected to the gates and a second conductor connected to the channels (i.e., connected to either the drains or sources of the channels or both depending upon design practicalities). By interconnecting the gates and channels, as just described, the various L-shaped transistors can form one larger capacitor (i.e., capacitor 130).

Forming capacitor 130 of L-shaped sections can reduce electromagnetically-induced eddy currents in capacitor 130, which tend to reduce the quality factor of inductor 110. In addition, capacitor 130 can shield inductor 110 from substrate 140 thereby improving the quality factor of inductor 110 (by reducing currents in the lossy substrate). By forming device 100 such that capacitor 130 is formed in a layered arrangement with respect to the inductor 110, instead of, for example, merely positioned next to inductor 110, the area occupied by capacitor 130 and inductor 110 is significantly reduced. In FIG. 1, for example, device 100 occupies only about half the area than would a device with inductor 110 merely positioned next to capacitor 130.

Inductor 110, for example, can be formed, in the generally upper metal layers of device 100, of a continuous series of conductors that form loops crossing at location 115 by passing between multiple layers of device 100. In other words, the loop inductor can include a number of loop-shaped conductors, each of which is formed on a corresponding layer of the device, and these loop-shaped conductors can be interconnected through the layers, e.g., using vias.

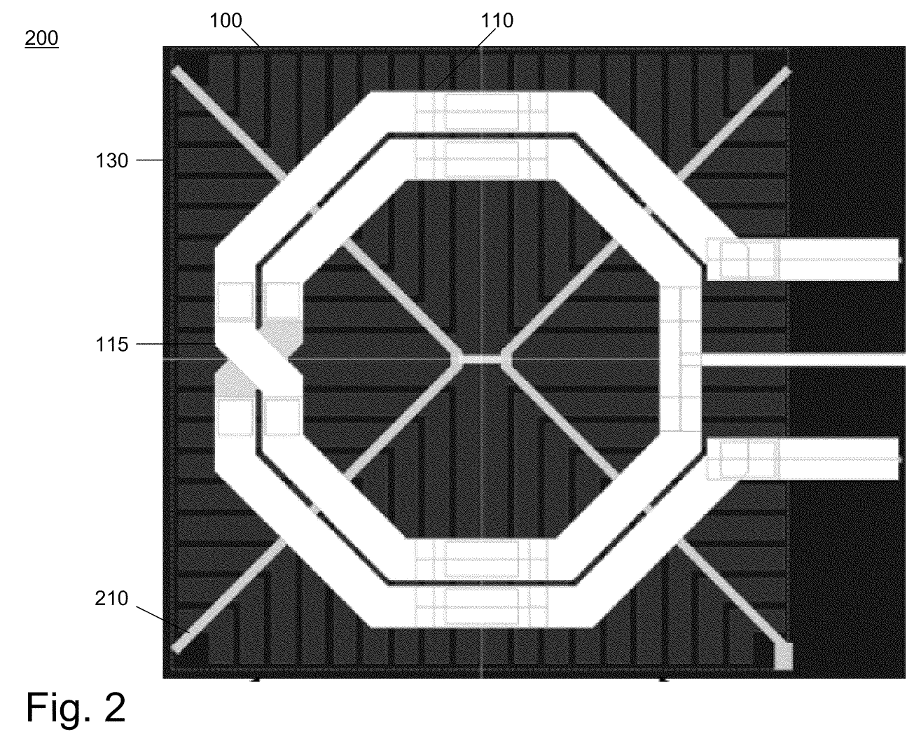

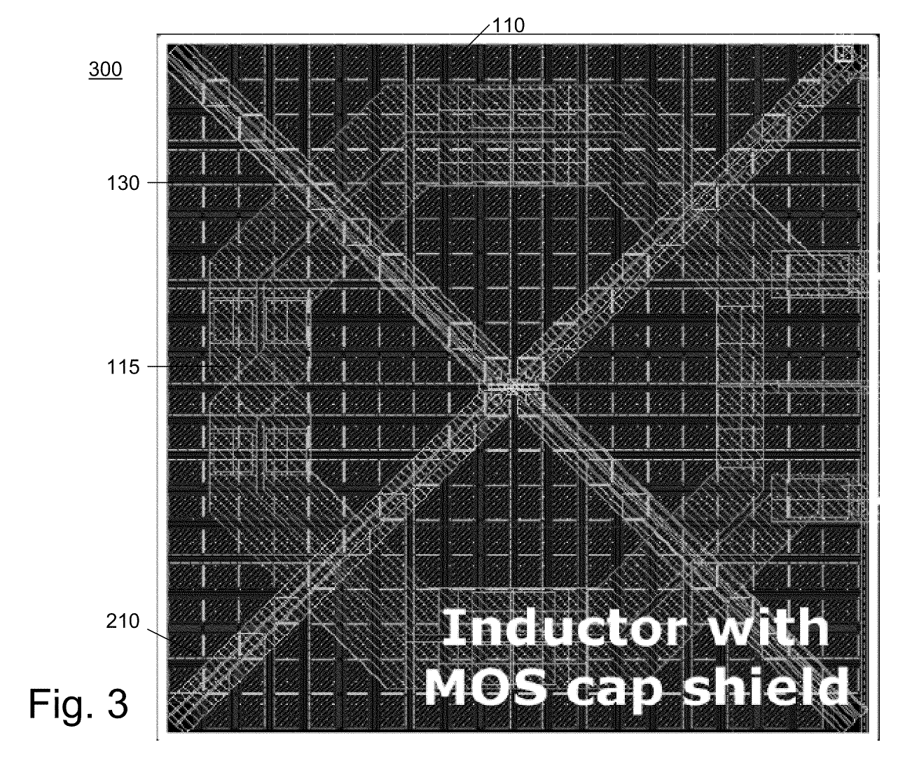

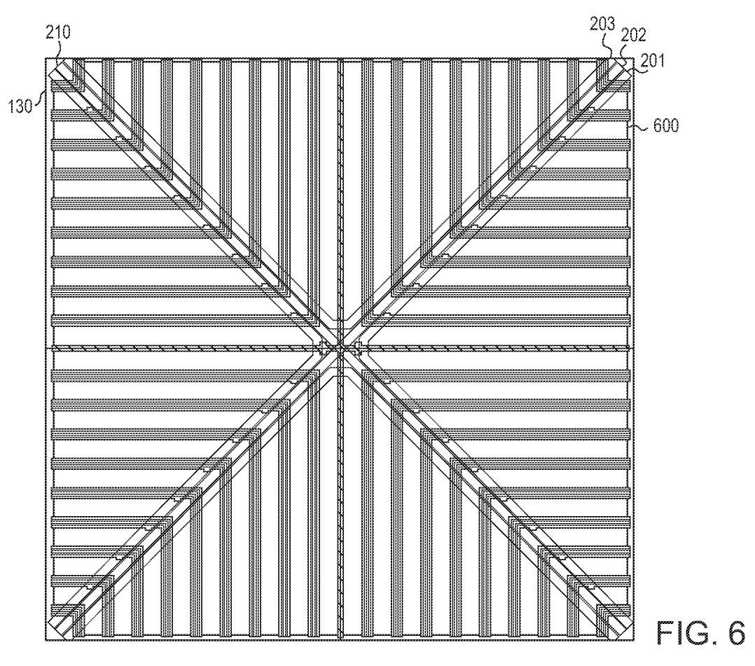

FIG. 2 is an illustration 200 of layered arrangement of an inductor and capacitor. The generally hexagonal structure is inductor 110. The X-shaped structure 210 is a group of conductors formed on an interconnection layer that connects the L-shaped sections together, so that the L-shaped sections form distributed capacitor 130. The connections are explained in further detail below, for example, in reference to FIGS. 6-9. FIG. 3 is a layout plot 300 of an embodiment of illustration 200, which also shows inductor 110 and L-shaped sections connected by X-shaped structure 210 forming capacitor 130.

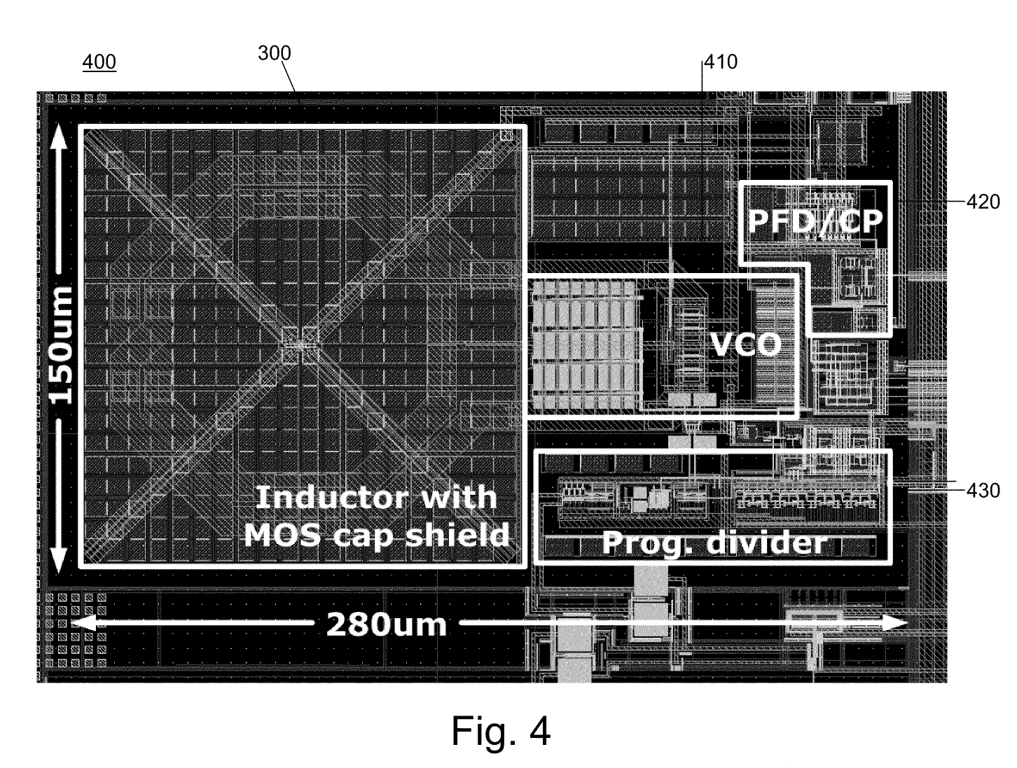

FIG. 4 is a layout plot 400, including plot 300, of device 100 and other components, such as, e.g., VCO 410, PFD/CP 420, and programmable divider 430. Plot 400 occupies approximately 42,000 um² (i.e., approximately 210 um×280 um). If capacitor 130 were located adjacent to plot 400, instead of being formed in a layered arrangement as part of plot 300, it would increase the size of plot 400 by 22,500 um² (i.e., 150 um×150 um) making plot 400 occupy 64,500 um² (i.e., 42,000 um²+22,500 um²), approximately a 53% increase in occupied area. This difference in area can be even greater (as a percentage) in devices in which the other circuitry occupies less area relative to the stacked inductor-capacitor arrangement.

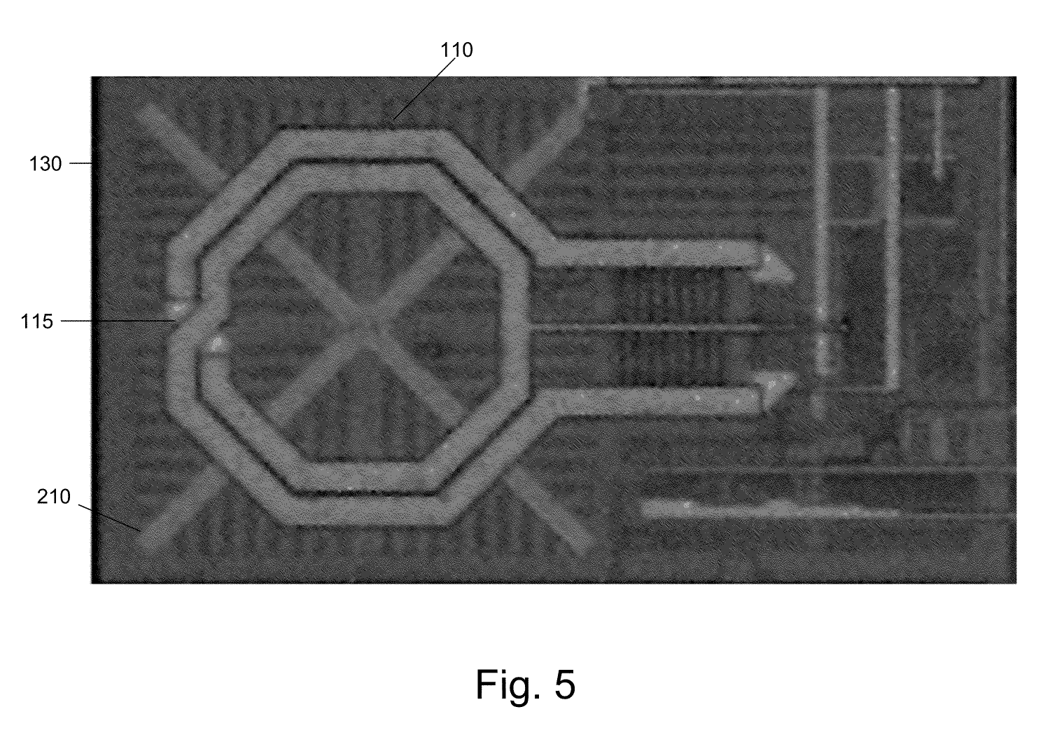

FIG. 5 shows a die photo of a fully-integrated PLL in 45 nm CMOS, including inductor 110, capacitor 130, and X-shaped interconnection structure 210. The chip prototypes are packaged, for example, in a 64-pin QFN package and are mounted on a PCB for testing. The chip operates with a nominal 0.85V supply and the VCO consumes 5 mA, the synthesizer 13 mA and the I/Q generation divide-by-2 and the output buffer 3 mA.

As discussed above, the various L-shaped transistors can be interconnected to form distributed capacitor 130. Some embodiments connect the various L-shaped transistors, for example, to avoid creating current loops in capacitor 130, by using X-shaped interconnection structure 210 as well as vias that pass between various metal layers of the device. FIGS. 6-9 illustrate these connections according to some embodiments.

FIG. 6 illustrates how X-shaped interconnection structure 210 connects the L-shaped sections to form distributed capacitor 130. Poly gate 600 is an example of gate 111 of FIG. 1. X-shaped interconnection structure 210 can be located on metal layer 2 (M2) and can include three conductors (conductor 201, conductor 202, and conductor 203) for connecting various terminals of the transistors. Conductor 201 can connect all the drains and sources together. Conductor 202 can connect all the bodies (i.e., the fourth terminal of the NMOS transistors) together. Conductor 203 can connect all the poly gates 600 of the NMOS transistors together. In some embodiments, conductor 201 can connect, for example, either all the drains together, or all the sources together.

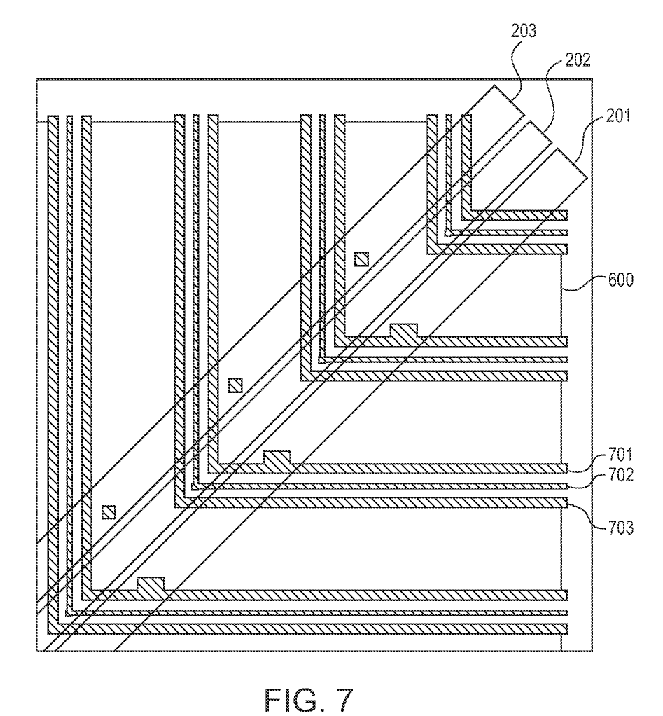

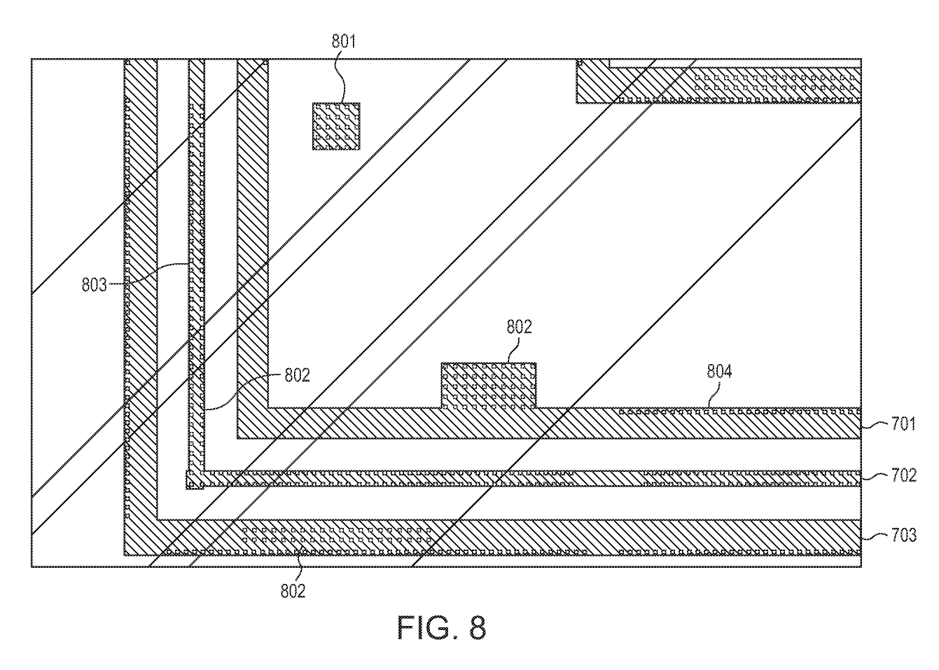

FIG. 7 is an enlarged version of the upper right corner of FIG. 6, including conductors 201, 202, and 203. Conductor 701 of metal layer one (M1) can connect to either the drain or source. Conductor 702 of M1 can connect to the body. Conductor 703 of M1 can connect to either the source or drain. FIG. 8 is an enlarged version of a portion of the mid-upper right of FIG. 7, including conductors 701, 702, and 703. Via 801 can connect the poly gate to conductor 203 of M2. Vias 802 can connect conductors 701, 702, and 703 of M1 through to conductors 201, 202, and 203 of M2, respectively. FIG. 8 also includes contacts 803 of M1 for connections to the body, and contacts 804 of M1 for connections to the drain or source.

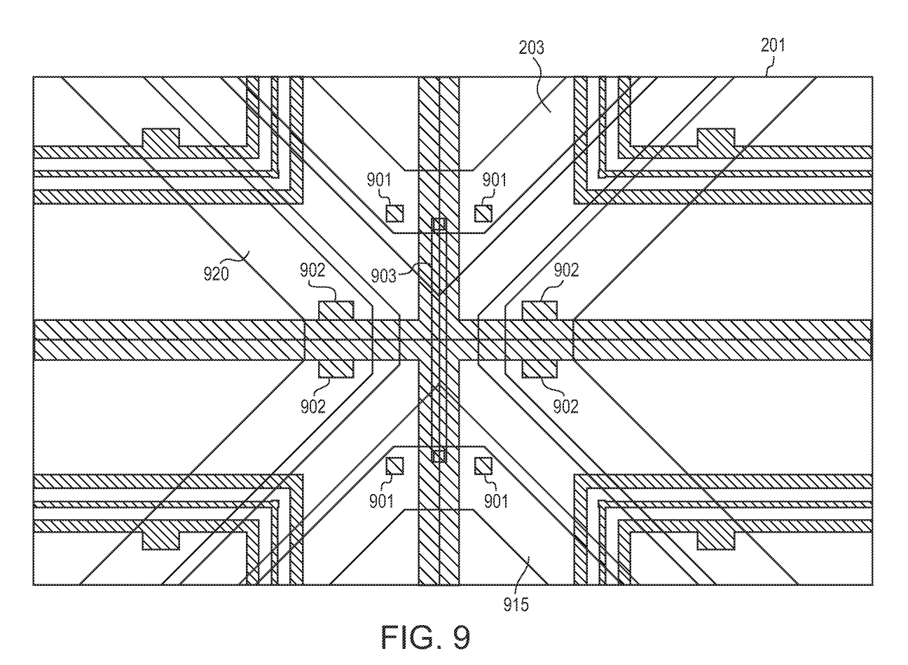

FIG. 9 is an enlarged version of the center of FIG. 6. Vias 901 can connect the poly gate of M1 to M2 so that the bridge 903 can connect M2, through M3, to connect the two M2 poly conductors together (i.e., 203 and 915 are connected using bridge 903 and vias 901). Vias 902 can connect the drain and source of M1 to M2 so that so that conductor 201 can be connected to conductor 920.

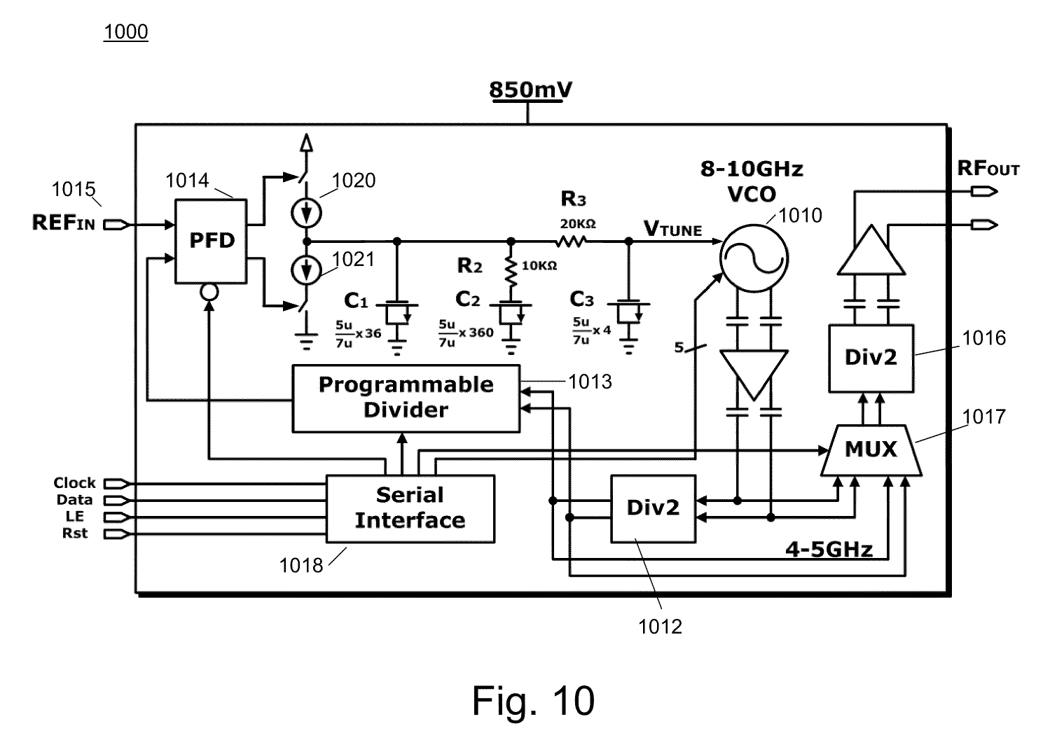

Device 100 can be used to construct various other devices. For example, FIG. 10 is a block diagram of a PLL synthesizer 1000 including VCO 1010 (which includes inductor 110) and capacitor C2 (which can be capacitor 130). VCO 1010 oscillates between 8 and 10 GHz and is locked to a 40 MHz external reference input 1015. The VCO signal output signal is buffered by buffer 1011 and drives fixed divide-by-2 divider 1012 in the loop which has an output frequency between 4 and 5 GHz. Programmable divider 1013 divides the signal further down to the reference frequency of input 1015 and feeds it back to tri-state phase/frequency detector (PFD) 1014. The input of additional divide-by-2 divider 1016 can be connected to the VCO buffer 1011 output or the fixed divide-by-2 divider 1012 in the loop and generates quadrature local oscillator output signals between 4 and 5.2 GHz or between 2 and 2.6 GHz. Whether divider 1016 is driven by buffer 1011 or divider 1012 can be controlled by multiplexer 1017.

Programmable divider 1013 can be a modular design of a cascade of six divide-by-⅔ dividers. The first four of these divide-by-⅔ dividers, divide-by-2 divider 1012, and divide-by-2 divider 1016 can be implemented using pseudo-differential CMOS logic cells using poly load resistors. The last two divide-by-⅔ dividers of programmable divider 113 can be implemented with standard CMOS logic gates. PFD 1014 can be a regular tri-state design with a lock detector. A charge pump can be implemented with source switched PMOS and NMOS current sources (current sources 1020 and 1021). Serial interface 1018 can control PFD 1014, programmable divider 1013, multiplexer 1017, and VCO 1010. FIG. 10 uses an integer-N topology. However, various topologies can be used. For example, the addition of a sigma-delta converter can convert the PLL into a fractional-N synthesizer, that, for example, may only incur small area and power increases.

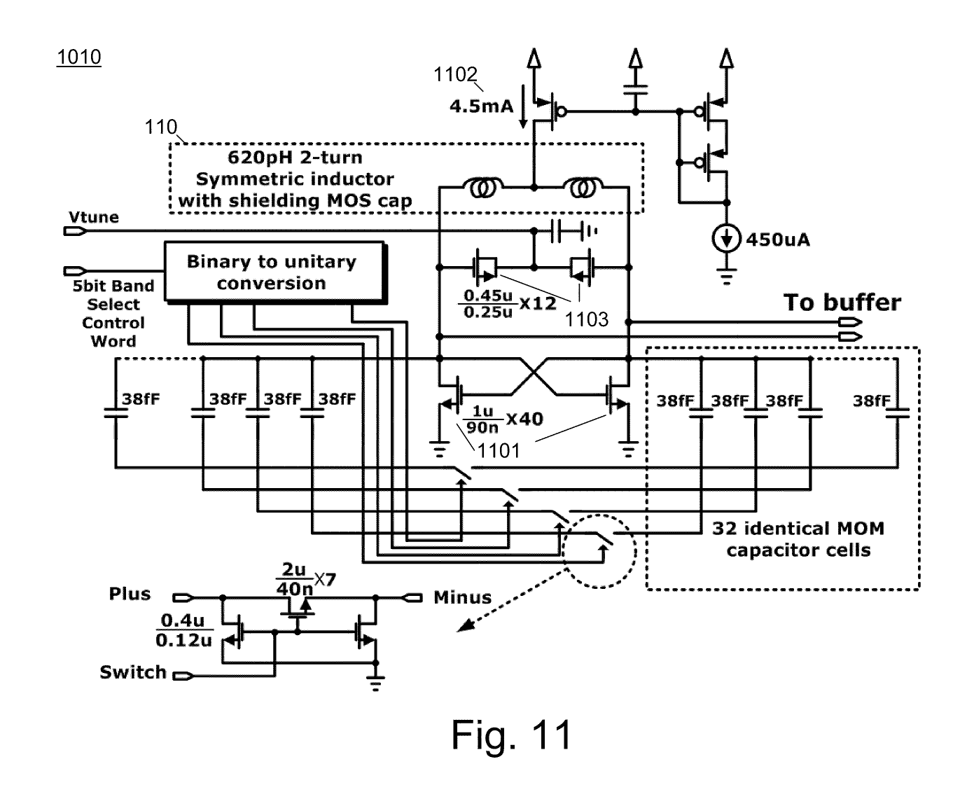

FIG. 11 is a more detailed diagram of VCO 1010 of FIG. 10. As shown, a top-biased VCO topology with an NMOS cross-coupled switching pair 1101 has been used. VCO 1010 is operated from a 0.85-V supply and through proper sizing of NMOS switching pair 1101 and the biasing current 1102, the common-mode level of the LC tank (including, e.g. the switched MOM capacitors cells, varactors connected to Vtune, parasitic capacitors of switching pair 1101, and the inductor) can be designed to be approximately 0.6V, such that the devices 1101 and 1103 are not over-stressed even when the tank operates with voltage limited swings (˜1.1. VPP). VCO 1010 uses differential switchable metal-oxide-metal (MOM) capacitors (the 38 fF capacitors) to provide discrete sub-band frequency-tuning switching across the entire frequency range, and the continuous tuning is implemented with an NMOS inversion-mode varactor (devices 203).

Returning to FIG. 10, the on-chip loop filter includes several grounded capacitors (C1, C2, and C3) that can be implemented, for example, with NMOS capacitors. Capacitor C2 in series with resistor R2 is the largest component, and can be, for example, formed of 360 elemental units, each of 5×7 um² (as discussed above C2 can be capacitor 130). In this 2nd order loop filter configuration, C2 does not need to have a high quality factor, because it is in series with resistor R2. Thus, MOS capacitors that offer a higher capacitance density, but have a lower quality factor, can be used. The reference spur performance of the PLL was limited by charge pump mismatches or charge pump-to-VCO power supply cross talk and is not affected by the gate leakage of the loop filter MOS capacitors.

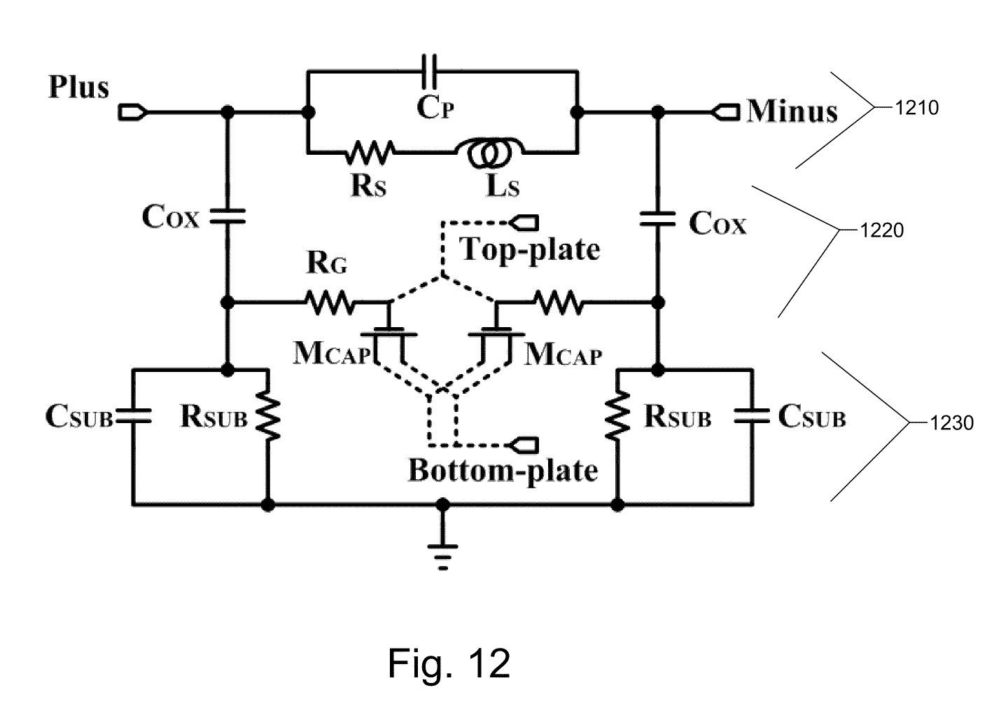

FIG. 12 shows an equivalent lumped model for the stacked MOS capacitor-inductor structure of FIG. 1. Area 1210 corresponds to inductor 110, area 1220 corresponds to capacitor 130, and area 1240 corresponds to substrate 140. FIG. 12 illustrates among other things, how the modeled components of 1230 and 1240 may allow current to travel parallel to area 1220 and reduce the quality factor of inductor 110.

In some embodiments, a DC bias is applied to the gates of the NMOS capacitors by the PLL to maintain the NMOS capacitor inverted. With different tuning voltages, the capacitance changes over a range of ±50% due to varying inversion levels. Capacitor 130 can improves the quality factor of the capacitive part of the inductor, especially when the inductor is driven differentially. Under differential drive, the differential capacitive currents through Cox can return through the poly gate and avoid the high losses in the substrate due to RSUB. The VCO can use a differential topology, and benefit from the presence of the NMOS capacitor poly gate shield.

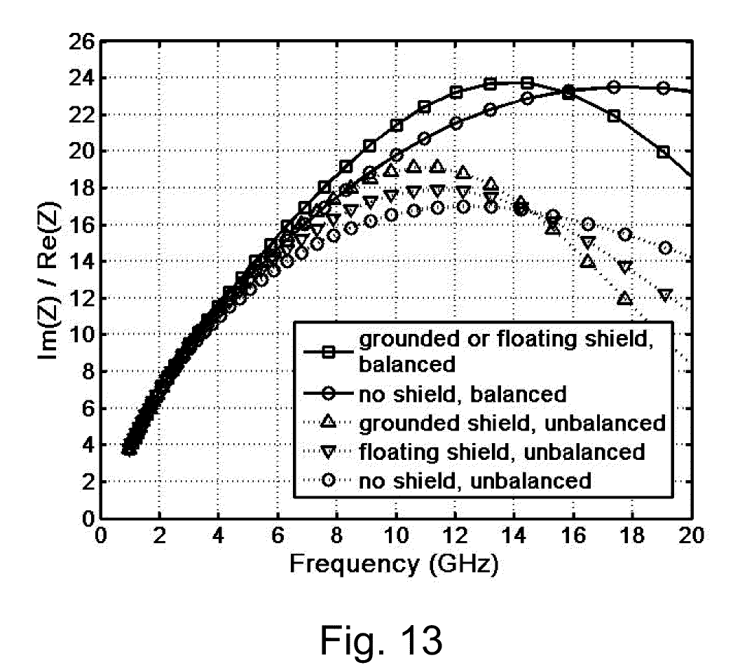

FIG. 13 shows the results of an electromagnetic simulation comparing the quality factor of an inductor without components underneath (‘no shield’), and with a stacked MOS capacitor with a grounded gate (‘grounded shield’) or with a floating gate (‘floating shield’) when measured in a balanced or unbalanced configuration. We note indeed an improvement of the balanced quality factor with a MOS cap underneath compared to a bare inductor. All metal and poly wiring was included in the simulation. The source and drain N+ regions were not included, but can be neglected since their resistivity is much large than the metal runners on top. A simulation with the poly gates replaced by metal showed a negligible change in the losses and the effect of the losses in the MOS channel is thus assumed to be negligible.

Scaling to smaller feature sizes allows the operation of the VCO and divider circuits at higher frequencies. This not only allows the easy generation of LO signals for multiple bands, it further allows the use of smaller on-chip planar inductors for the VCO to save area.

Embodiments of the disclosed subject matter can be combined with embodiments of the subject matter of U.S. patent application Ser. No. 11/943,287, filed Nov. 20, 2007, which is hereby incorporated by reference herein in its entirety.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways within the scope and spirit of the invention.

What is claimed is:

1. A multilayer integrated circuit, comprising:
a semiconductor substrate including a plurality of channels extending into the substrate from a surface of the substrate;
a distributed capacitor comprising a plurality of gates formed on the surface of the substrate over the channels, and further comprising an insulator between the gates and the channels, the gates being spaced apart along the surface of the substrate;
an interconnect layer formed over the distributed capacitor, the interconnect layer comprising a plurality of conductors, at least a first conductor being connected to at least some of the gates and at least a second conductor being connected to at least some of the channels; and
an inductor formed over the interconnect layer, the inductor comprising at least conductor arranged on a layer.

2. The integrated circuit of claim 1, wherein the conductor of the inductor is substantially loop-shaped.

3. The integrated circuit of claim 1, wherein the conductor of the inductor forms a spiral.

4. The integrated circuit of claim 1, wherein the conductor of the inductor forms a solid area.

5. The integrated circuit of claim 1, wherein the distributed capacitor is formed of a plurality of L-shaped gates.

6. The integrated circuit of claim 5, wherein the L-shaped gates are arranged into quadrants of a rectangular array, and within each quadrant the L-shaped gates are nested in decreasing size order and are arranged with their corners pointing toward a center of the rectangular array.

7. The integrated circuit of claim 6, wherein the interconnect layer comprises an X-shaped arrangement of conductors, including the at least first conductor and the at least second conductor, with the conductors arranged to cross over the corners of the L-shaped gates, such that a center of the X-shaped arrangement is positioned above the center of the rectangular array.

8. The integrated circuit of claim 1, the second conductor is connected to a drain of each of the channels to which the second conductor is connected.

9. The integrated circuit of claim 1, the second conductor is connected to a source of each of the channels to which the second conductor is connected.

10. The integrated circuit of claim 1, further comprising at least a first circuit layer between the distributed capacitor and the interconnect layer and at least a second circuit layer between the interconnect layer and the loop inductor.

11. The integrated circuit of claim 1, wherein the channels and gates of the distributed capacitor form NMOS devices.

12. The integrated circuit of claim 1, wherein the channels and gates of the distributed capacitor form PMOS devices.

13. The integrated circuit of claim 1, wherein the inductor forms part of a voltage controlled oscillator.

14. The integrated circuit of claim 1, wherein the inductor comprises a plurality of loop-shaped conductors, each of the loop-shaped conductors being formed on a corresponding layer, the loop-shaped conductors being interconnected through the layers.

15. The integrated circuit of claim 1, wherein the inductor and the distributed capacitor form a resonant circuit.
